(19) United States
(12) Patent Application Publication
(10) Pub. No.: US 2026/0354117 A1
(43) Pub. Date: Nov. 5, 2026

(54) BONDING APPARATUS AND METHOD OF MANUFACTURING AN INTEGRATED CIRCUIT PACKAGE USING THE APPARATUS

(71) Applicant: Taiwan Semiconductor Manufacturing Co., Ltd., Hsinchu (TW)

(72) Inventors: Jen-Hao Liu, Zhunan Township (TW); Amram Eitan, Hsinchu (TW); Chih-Yuan Chiu, Zhudong Township (TW); Chi-Chun Peng, Hsinchu (TW); Yu-Hong Du, Hsinchu (TW)

(21) Appl. No.: 19/744,100

(22) Filed: Jul. 16, 2026

Related U.S. Application Data
(62) Division of application No. 18/451,982, filed on Aug. 18, 2023.

(51) Int. Cl. H10P 72/78; H10P 72/76; H10W 72/00; H10W 80/00

(52) U.S. Cl. CPC H10P 72/78; H10P 72/7604; H10W 72/019; H10W 72/071; H10W 72/07231; H10W 72/07233; H10W 72/07235; H10W 72/07332; H10W 72/07632; H10W 72/07633; H10W 80/312; H10W 80/327

(57) ABSTRACT

A bonding apparatus with a bonding head having vacuum channels and switchable channels, and the method of forming an integrated circuit package are provided. The bonding apparatus may include a vacuum pump, a blower, a controller communicatively coupled to the vacuum pump and the blower, and a bonding head. The bonding head may include a main body, a first vacuum channel in the main body, wherein the first vacuum channel is connected to the vacuum pump, and a first switchable channel in the main body, wherein the first switchable channel is connected to the vacuum pump and the blower.

### CROSS-REFERENCE TO RELATED APPLICATIONS

This application is a divisional of U.S. Patent Application No. 18/451,982 filed on Aug. 18, 2023, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, and FIG. 1C illustrate aspects of a bonding apparatus, in accordance with some embodiments.

FIGS. 2A, 2B, 3, 4A, 4B, 5, 6, and FIG. 7A illustrate a pick-and-place process by the bonding apparatus, in accordance with some embodiments.

FIG. 7B illustrates a process flow of the pick-and-place process by the bonding apparatus, in accordance with some embodiments.

FIGS. 8, 9, 10, and FIG. 11 illustrate cross-sectional views of intermediate stages of the manufacturing of an integrated circuit package, in accordance with some embodiments.

FIGS. 12A and 12B illustrate aspects of a bonding apparatus, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A bonding apparatus and a method of manufacturing an integrated circuit package using the bonding apparatus are provided. In accordance with some embodiments, the bonding apparatus may comprise a bonding head, a vacuum pump, a blower, and a controller. The bonding head may comprise vacuum channels and switchable channels, which may be switched between a vacuum mode and a blowing mode by the controller. The manufacturing an integrated circuit package may comprise placing an integrated circuit die on a wafer structure and bonding the integrated circuit die and a wafer structure. By utilizing the bonding apparatus to place the integrated circuit die on the wafer structure, the integrated circuit die may be first warped, then gradually flattened on the wafer structure, which may reduce or prevent voids between the integrated circuit die and the wafer structure during the bonding process, thereby improving the yield and the reliability of the integrated circuit package.

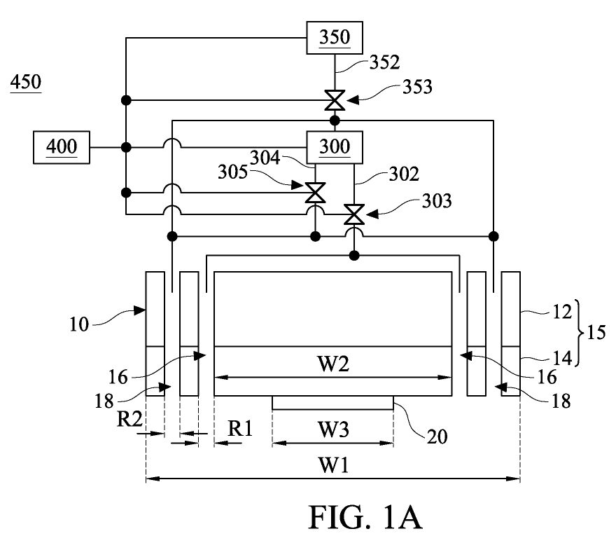

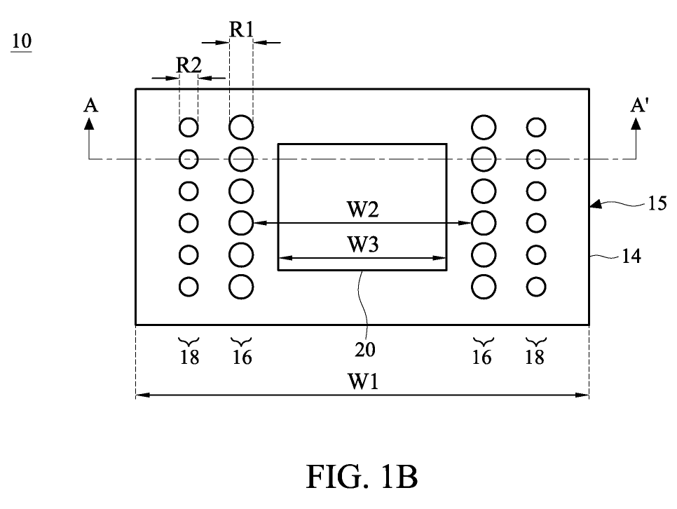

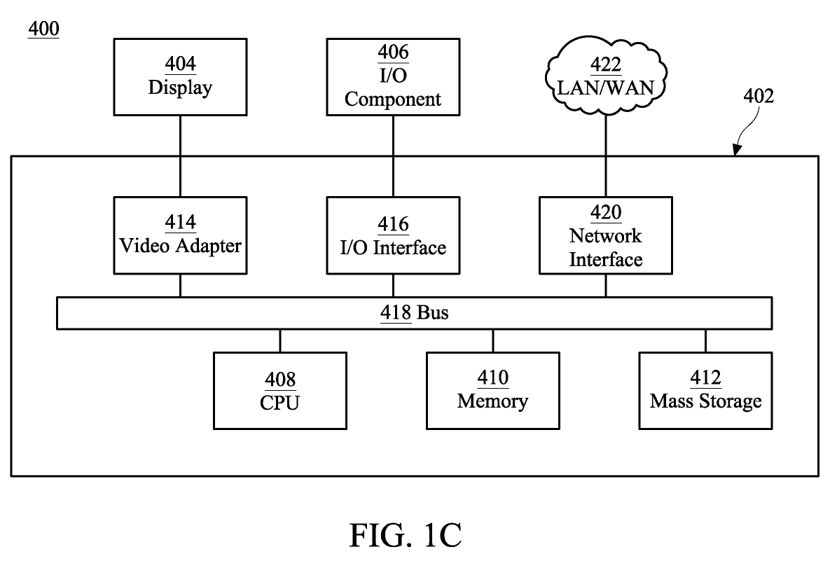

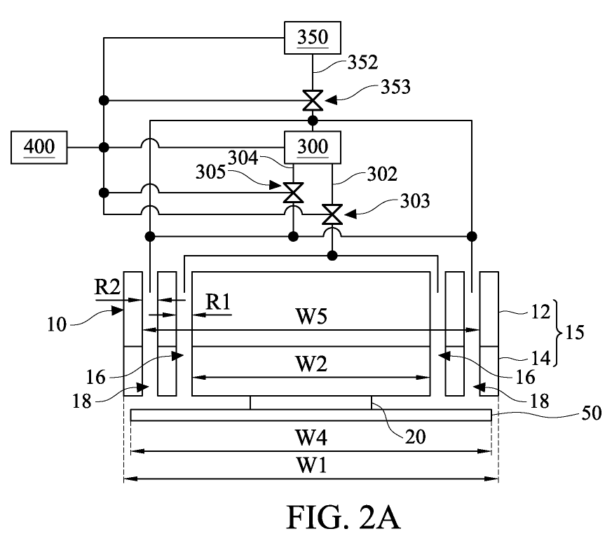

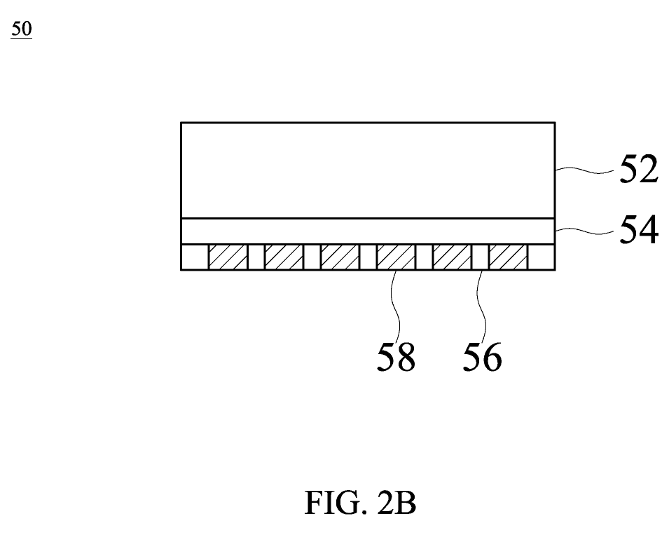

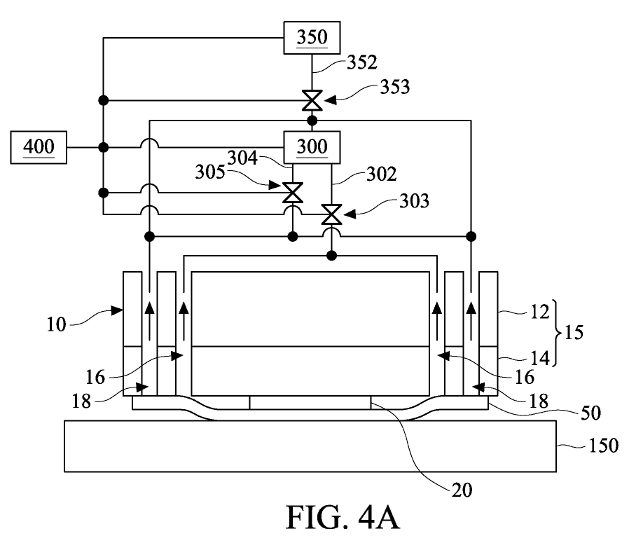

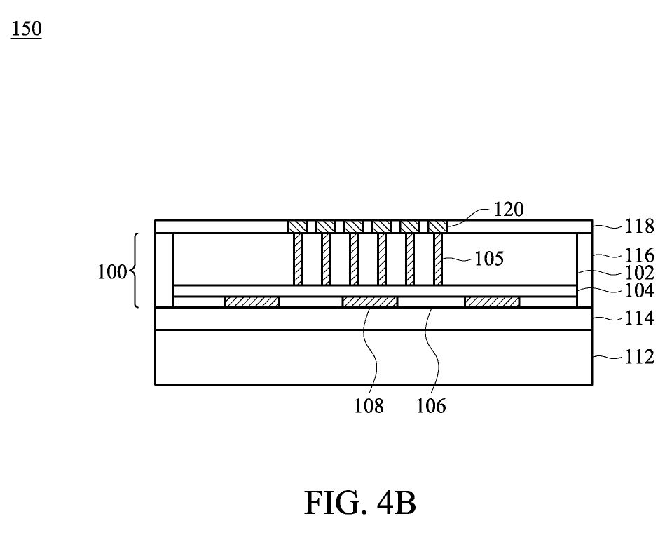

FIG. 1A shows aspects of a bonding apparatus 450 including a bonding head 10, a vacuum pump 300 connected to the bonding head 10, a blower 350 connected to the bonding head 10, and a controller 400 communicatively coupled to the vacuum pump 300 and the blower 350. The bonding apparatus 450 may be used to perform a pick-and-place process, wherein the controller 400 may be configured to direct a first substrate to be placed on a second substrate by the bonding head 10. In some embodiments, the first substrate is a top integrated circuit die 50 (shown in FIGS. 2A and 2B) and the second substrate is a wafer structure 150 (shown in FIGS. 4A and 4B), and the pick-and-place process is a part of the manufacturing of an integrated circuit package. The description of the pick-and-place process utilizing the bonding apparatus 450 below uses such embodiments as an example. By controlling actions taken by the bonding head 10, the vacuum pump 300, the blower 350, and various valves, the controller 400 may be configured to first warp the top integrated circuit die 50, then gradually flatten the top integrated circuit die 50 (e.g., from a central portion to peripheral portions of the integrated circuit die) on the wafer structure 150, which may reduce or prevent voids between the top integrated circuit die 50 and the wafer structure 150 in a subsequent annealing process, thereby improving the yield and the reliability of the integrated circuit package.

The bonding head 10 comprises a base 12 and an adapter 14 on a bottom surface of the base 12. The base 12 and the adapter 14 may be collectively referred to as a main body 15. A protrusion 20 is disposed on a bottom surface of the adapter 14. The adapter 14, along with the protrusion 20, may be disconnected from the base 12 and a different adapter with a different protrusion may be connected to the base 12, as described in greater detail below. A vacuum channel 16 and a switchable channel 18 are disposed on each side of the main body 15. Each switchable channel 18 is disposed between a sidewall of the main body 15 and the corresponding vacuum channel 16 on the same side of the main body 15. In some embodiments, the vacuum channels 16 and the switchable channels 18 are perpendicular to the bottom surface of the adapter 14.

The vacuum channels 16 and the switchable channels 18 are connected to the vacuum pump 300 by vacuum lines 302 and vacuum lines 304, respectively, so that the vacuum pump 300 may create vacuum in the vacuum channels 16 and the switchable channels 18 as directed by the controller 400. A vacuum valve 303 and a vacuum valve 305 are disposed on main lines of the vacuum lines 302 and the vacuum lines 304, respectively, and are communicatively coupled to the controller 400. The switchable channels 18 are connected to the blower 350 by gas lines 352, so that the blower 350, such as a mechanical blower, a compressed gas tank, or the like, may blow gas (e.g., air, nitrogen gas) through the switchable channels 18 as directed by the controller 400. A gas valve 353 is disposed on a main line of the gas lines 352 and is communicatively coupled to the controller 400. By directing the actions taken by the vacuum pump 300, the blower 350, the vacuum valve 303, the vacuum valve 305, and the gas valve 353, the controller 400 may direct actions in the vacuum channels 16 and the switchable channels 18 during the pick-and-place process as described in greater detail below. The bonding apparatus 450 may also include a motorized arm (not separately illustrated) that is connected to the bonding head 10 and communicatively coupled to the controller 400, so that the controller 400 may also direct the movement of the bonding head 10 during the pick-and-place process.

The adapter 14 of the main body 15 may have a width W1. The width W1 may be a distance from a first sidewall of the adapter 14 to a second sidewall of the adapter 14 opposite to the first sidewall. The vacuum channel 16 on a first side of the main body 15 may be spaced apart from the vacuum channel 16 on a second side of the main body 15 by a width W2, the second side being opposite to the first side. The width W2 may be a distance from an inner sidewall of the vacuum channel 16 on the first side of the main body 15 to an inner sidewall of the vacuum channel 16 on the second side of the main body 15. The width W2 may be larger than about half of the width W1. In some embodiments, the width W1 is larger than about 15 mm and the width W2 is larger than about 7.5 mm. The protrusion 20 may have a width W3 smaller than the width W2. The width W2 being larger than about half of the width W1 may lead to a width W3 of the protrusion 20 large enough to result in certain warpage of the integrated circuit die attached to the bonding head 10, which may be beneficial to the manufacturing of an integrated circuit package as described in greater detail below. FIG. 1A illustrates the base 12 and the adapter 14 of the main body 15 having a same width as an example. In some embodiments, the base 12 and the adapter 14 may have different widths.

Top openings of the vacuum channels 16 and the switchable channels 18 may be connected with distribution manifolds (not separately illustrated), which are connected to the vacuum lines 302, the vacuum lines 304, and the gas lines 352. FIG. 1A illustrates the vacuum channels 16 and the switchable channels 18 extending through the main body 15 as an example, which corresponds to the embodiments where the distribution manifolds are disposed outside the bonding head 10. In some embodiments, the distribution manifolds are disposed inside the bonding head 10, wherein the vacuum channels 16 and the switchable channels 18 extend within the main body 15. The base 12 and the adapter 14 may comprise rigid materials, such as ceramic, metal, the like, or a combination thereof. In some embodiments, the base 12 and the adapter 14 may comprise a same material.

FIG. 1B shows a bottom-up view of the bonding head 10. The cross-sectional view of the bonding head 10 shown in FIGS. 1A may be obtained from the reference cross-section A-A’ in FIG. 1B, wherein like reference numerals refer to like features. As shown in FIG. 1B, a first plurality of the vacuum channels 16 may be disposed on the first side of the main body 15 and a second plurality of the vacuum channels 16 may be disposed on the second side of the main body 15. The protrusion 20 may be disposed on a central portion of the bottom surface of the adapter 14 and between the first plurality of the vacuum channels 16 and the second plurality of the vacuum channels 16. A first plurality of the switchable channels 18 may be disposed between a first edge of the main body 15 on the first side and the first plurality of the vacuum channels 16, and a second plurality of the switchable channels 18 may be disposed between a second edge of the main body 15 on the second side and the second plurality of the vacuum channels 16.

The vacuum channels 16 and the switchable channels 18 may have circular bottom openings. The bottom openings of the vacuum channels 16 may have a diameter R1 and the bottom openings of the switchable channels 18 may have a diameter R2. The diameter R1 may be larger than or equal to the diameter R2. In some embodiment, the diameter R1 and the diameter R2 may be larger than about 0.1 mm. As described in greater detail below, the bottom openings of the vacuum channels 16 and the switchable channels 18 may exert an attaching force on the integrated circuit die and the bottom openings of the switchable channels 18 may exert a blowing force on the integrated circuit die in separate subsequent steps of the pick-and-place process, the diameter R1 and the diameter R2 being larger than about 0.1 mm may lead to sufficient attaching force and blowing force on the integrated circuit die, thereby improving the yield and the reliability of the integrated circuit package. The bottom openings of each plurality of the vacuum channels 16 and the switchable channels 18 may be arranged in a column extending along the first edge and the second edge of the main body 15. The top openings of the vacuum channels 16 and the switchable channels 18 may have same shapes and sizes as the bottom openings of the vacuum channels 16 and the switchable channels 18.

FIG. 1C illustrates aspects of the controller 400, in accordance with some embodiments. The controller 400 may be any form of computer processor that can be used in an industrial setting for controlling process machines. In an embodiment, the controller 400 comprises a processing unit 402, such as a desktop computer, a workstation, a laptop computer, or a dedicated unit customized for a particular application. The controller 400 may be equipped with a display 404 and one or more input/output components 406. The processing unit 402 may include a central processing unit (CPU) 408, memory 410, a mass storage device 412, a video adapter 414, and an input/output (I/O) interface 416 connected to a bus 418.

The bus 418 may be one or more of any type of several bus architectures including a memory bus or memory controller, a peripheral bus, or video bus. The CPU 408 may comprise any type of electronic data processor, and the memory 410 may comprise any type of system memory, such as static random access memory (SRAM), dynamic random access memory (DRAM), or read-only memory (ROM). The mass storage device 412 may comprise any type of storage device configured to store data, programs, and other information and to make the data, programs, and other information accessible via the bus 418. The mass storage device 412 may comprise, for example, one or more of a hard disk drive, a magnetic disk drive, or an optical disk drive. The memory 410 and/or mass storage device 412 may be a non-transitory computer readable medium having programming stored thereon. The programming may comprise instructions that, when executed by the CPU 408, cause the controller 400 to perform the controlling functionality described herein.

The video adapter 414 and the I/O interface 416 provide interfaces to couple external input and output devices to the processing unit 402. As illustrated in FIG. 1C, examples of input and output devices include the display 404 communicatively coupled to the video adapter 414 and the I/O component 406, such as a mouse, keyboard, printer, and the like, communicatively coupled to the I/O interface 416. Other devices may be communicatively coupled to the processing unit 402, and additional or fewer interface cards may be utilized. For example, a serial interface card (not shown) may be used to provide a serial interface for a printer. The processing unit 402 also may include a network interface 420 that may be a wired link and/or a wireless link to a local area network (LAN) or a wide area network (WAN) 422. It should be noted that the controller 400 may include other components. For example, the controller 400 may include power supplies, cables, a motherboard, removable storage media, cases, and the like. These other components, although not shown in FIG. 1C, are considered part of the controller 400.

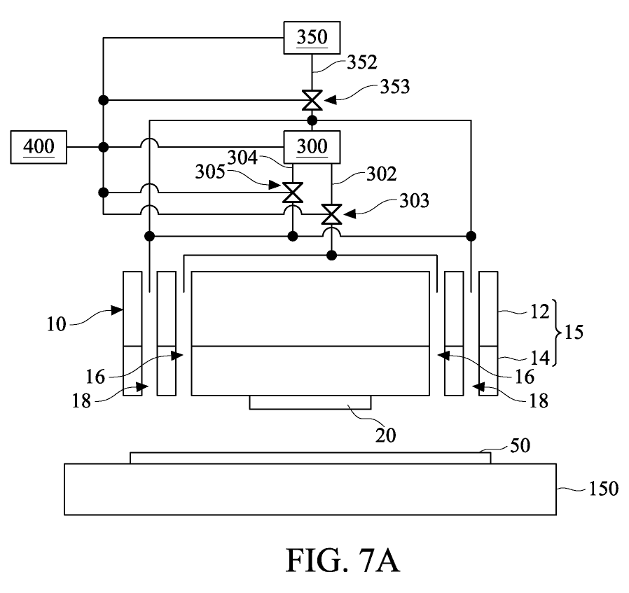

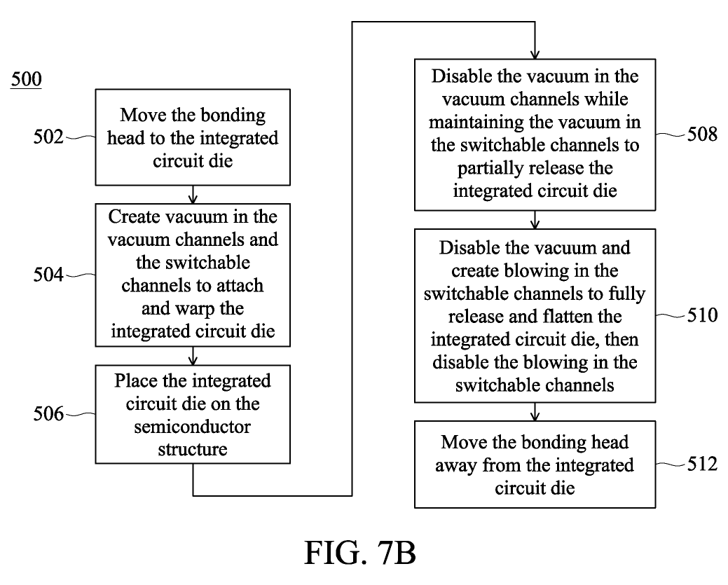

FIGS. 2A, 2B, 3, 4A, 4B, 5, 6, and 7A illustrate a pick-and-place process and a bonding process by the bonding apparatus 450, in accordance with some embodiments, wherein a top integrated circuit die 50 is placed on and bonded to a wafer structure 150 by the bonding apparatus 450 as a part of the manufacturing of the integrated circuit package. The pick-and-place process may comprise multiple steps, which are reflected schematically in a process flow 500 shown in FIG. 7B.

In FIG. 2A, the bonding head 10 is directed by the controller 400 to move to the top integrated circuit die 50. In some embodiments, a bottom surface of the protrusion 20 is in contact with a top surface of the top integrated circuit die 50. The respective process is illustrated as step 502 in the process flow 500 shown in FIG. 7B. The top integrated circuit die 50 may have a width W4. The width W1 of the main body 15 may be larger than the width W4. An outer sidewall of the switchable channel 18 on the first side of the main body 15 may be spaced apart from an outer sidewall of the switchable channel 18 on the second side of the main body 15 by a width W5. The width W4 of the top integrated circuit die 50 may be larger than the width W5. As described in greater detail below, the top integrated circuit die 50 may be attached to the main body 15 in subsequent steps of the pick-and-place process, the width W4 of the top integrated circuit die 50 being smaller than the width W1 and larger than the width W5 may lead to a more secure attachment of the top integrated circuit die 50, thereby improving the yield and the reliability of the integrated circuit package.

FIG. 2B illustrates aspects of the top integrated circuit die 50, in accordance with some embodiments. The top integrated circuit die 50 may be a logic die (e.g., CPU, graphics processing unit (GPU), system-on-a-chip (SoC), application processor (AP), microcontroller, etc.), a memory die (e.g., DRAM die, SRAM die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), the like, or combinations thereof.

The top integrated circuit die 50 may have a semiconductor substrate 52, such as silicon, doped or undoped, or an active layer of a semiconductor-on-insulator (SOI) substrate. The semiconductor substrate 52 may include other semiconductor materials, such as germanium, silicon carbide, gallium arsenic, gallium phosphide, indium phosphide, indium arsenide, indium antimonide, SiGe, GaAsP, AlInAs, AlGaAs, GaInAs, GaInP, and/or GaInAsP, or combinations thereof. The semiconductor substrate 52 may have an active surface (e.g., the surface facing downwards in FIG. 2B), which may be called a front side, and an inactive surface (e.g., the surface facing upwards in FIG. 2B), which may be called a back side.

Devices (not separately illustrated) may be disposed at the active surface of the semiconductor substrate 52. The devices may be active devices (e.g., transistors, diodes, etc.), capacitors, resistors, or the like. An interconnect structure 54 may be disposed over the active surface of the semiconductor substrate 52. The interconnect structure 54 may interconnect the devices to form an integrated circuit. The interconnect structure 54 may be formed of metallization patterns (not separately shown) in dielectric layers (not separately shown). The dielectric layers may be low-k dielectric layers. The metallization patterns may include metal lines and vias, which may be formed in the dielectric layers by a damascene process, such as a single damascene process, a dual damascene process, or the like. The metallization patterns may be formed of a suitable conductive material, such as copper, tungsten, aluminum, silver, gold, a combination thereof, or the like. The metallization patterns are electrically connected to the devices.

A bonding layer 56 may be disposed on the interconnect structure 54. The bonding layer 56 may be formed of an oxide, such as silicon oxide, phosphosilicate glass (PSG), borosilicate glass (BSG), boron-doped phosphosilicate glass (BPSG), a tetraethyl orthosilicate (TEOS) based oxide, or the like; a nitride, such as silicon nitride or the like. The bonding layer 56 may be formed by chemical vapor deposition (CVD), atomic layer deposition (ALD), or the like. One or more passivation layer(s) (not separately illustrated) may be disposed between the bonding layer 56 and the interconnect structure 54. Die connectors 58 may extend through the bonding layer 56. The die connectors 58 may include pads, conductive pillars, or the like, to which external connections can be made. In some embodiments, the die connectors 58 include bond pads at the front side of the top integrated circuit die 50 and vias that connect the bond pads to the metallization pattern of the interconnect structure 54. The die connectors 58, including the bond pads and the vias, may be formed by a damascene process, such as a single damascene process, a dual damascene process, or the like. The die connectors 58 may be formed of a conductive material, such as copper, aluminum, or the like, by a technique, such as plating or the like. A planarization process such as a chemical-mechanical polishing (CMP), a grinding process, an etch-back process, combinations thereof, or the like, may be performed on the bonding layer 56 and the die connectors 58. In some embodiments, after the planarization process, surfaces of the bonding layer 56 and the die connectors 58 may be substantially coplanar or level (within process variations).

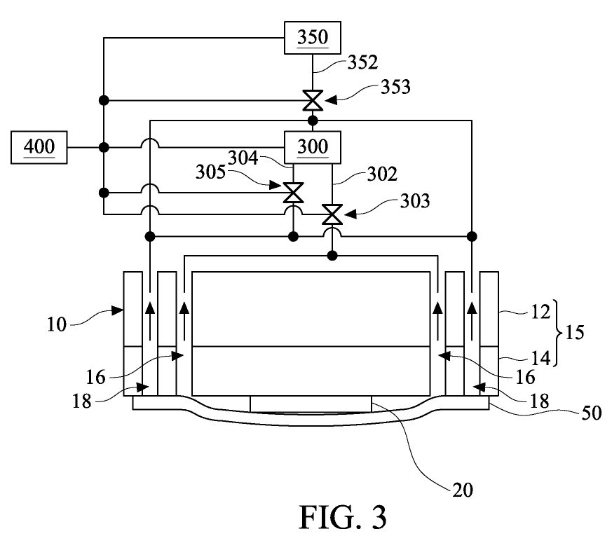

In FIG. 3, the controller 400 creates vacuum (e.g., negative pressure) in the vacuum channels 16 and the switchable channels 18 simultaneously to attach and warp the top integrated circuit die 50 by activating the vacuum pump 300, and opening the vacuum valve 303 and the vacuum valve 305. The respective process is illustrated as step 504 in the process flow 500 shown in FIG. 7B. When the controller 400 creates the vacuum in the vacuum channels 16 and the switchable channels 18, the bottom openings of the vacuum channels 16 and the switchable channels 18 may exert an attaching force on the top integrated circuit die 50. Peripheral portions of the top integrated circuit die 50 disposed underneath the bottom openings of the vacuum channels 16 and the switchable channels 18 may be attached to and in contact with the bottom surface of the adapter 14 and a central portion of the top integrated circuit die 50 disposed underneath the protrusion 20 may be in contact with the protrusion 20. As a result, the top integrated circuit die 50 may be warped by the bonding head 10, wherein the central portion of the top integrated circuit die 50 may be spaced apart from the bottom surface of the adapter 14 by the protrusion 20, while the peripheral portions of the top integrated circuit die 50 may be in contact with the bottom surface of the adapter 14. In some embodiments, the top integrated circuit die 50 is warped into a shape of a bow. In some embodiments, a gap is disposed between the central portion of the top integrated circuit die 50 and the bottom surface of the protrusion 20 after the top integrated circuit die 50 is warped.

In FIG. 4A, the bonding head 10 is directed by the controller 400 to place the top integrated circuit die 50 on the wafer structure 150, wherein the central portion of the top integrated circuit die 50 may be flattened and may be in contact with a top surface of the wafer structure 150 as well as the bottom surface of the protrusion 20, while the peripheral portions of the top integrated circuit die 50 may be spaced apart from the top surface of the wafer structure 150. The respective process is illustrated as step 506 in the process flow 500 shown in FIG. 7B. An activation process (not shown) may be done on a bottom surface of the top integrated circuit die 50 and the top surface of the wafer structure 150 prior to placing the top integrated circuit die 50 on the wafer structure 150. The activation process may comprise water rinsing, plasma treatment, and the like, which prepares the bottom surface of the top integrated circuit die 50 and the top surface of the wafer structure 150 for bonding upon making contact as described in greater detail below. The warpage of the top integrated circuit die 50 formed in the previous step may facilitate the expulsion of air from an interface between the central portion of the top integrated circuit die 50 and the wafer structure 150 as the top integrated circuit die 50 is gradually flattened by the protrusion 20 on the top surface of the wafer structure 150, which may reduce or prevent voids between the top integrated circuit die 50 and the wafer structure 150 during the bonding process, thereby improving the yield and the reliability of the integrated circuit package.

FIG. 4B illustrates aspects of the wafer structure 150, in accordance with some embodiments. The wafer structure 150 may include a bottom integrated circuit die 100 on a carrier 112, a gap-fill layer 116 on the carrier 112 and surrounding the bottom integrated circuit die 100, a bonding layer 118 on the bottom integrated circuit die 100 and the gap-fill layer 116, and die connectors 120 extending through the bonding layer 118. The carrier 112 may be a semiconductor carrier, a glass carrier, a ceramic carrier, or the like, with a size of a wafer. The bottom integrated circuit die 100 may be attached to the carrier 112 by an adhesive 114. In some embodiments, the adhesive 114 is a thermal-release layer, such as an epoxy-based light-to-heat-conversion (LTHC) release material, which loses its adhesive property when heated. In some embodiments, the adhesive 114 is a UV glue, which loses its adhesive property when exposed to UV light.

The bottom integrated circuit die 100 may be a logic die (e.g., CPU, GPU, SoC, AP, microcontroller, etc.), a memory die (e.g., DRAM die, SRAM die, etc.), a power management die (e.g., PMIC die), a RF die, a sensor die, a MEMS die, a signal processing die (e.g., DSP die), a front-end die (e.g., AFE die), the like, or combinations thereof. The materials and manufacturing processes of the features in the bottom integrated circuit die 100 may be found by referring to the like features in the top integrated circuit die 50. The bottom integrated circuit die 100 may include a semiconductor substrate 102, which may have an active surface (e.g., the surface facing downwards in FIG. 4B), which may be called a front side, and an inactive surface (e.g., the surface facing upwards in FIG. 4B), which may be called a back side. Devices (not separately illustrated) may be disposed at the active surface of the semiconductor substrate 102. The devices may be active devices (e.g., transistors, diodes, etc.), capacitors, resistors, or the like. An interconnect structure 104 may be disposed on the active surface of the semiconductor substrate 102. The interconnect structure 104 may be formed of metallization patterns (not separately shown) in dielectric layers (not separately shown). Conductive vias 105 may extend through the semiconductor substrate 102 and electrically connected to the metallization patterns of the interconnect structure 104. The conductive vias 105 may be referred to as through-substrate vias (TSV). A bonding layer 106 may be disposed on the interconnect structure 104. One or more passivation layer(s) (not separately illustrated) may be disposed between the bonding layer 106 and the interconnect structure 104. Die connectors 108 may extend through the bonding layer 106 and may be electrically connected to the metallization patterns of the interconnect structure 104.

The gap-fill layer 116 may be an insulating layer and may be formed of a dielectric material, such as silicon oxide, PSG, BSG, BPSG, a TEOS based oxide, or the like, which may be formed by a suitable deposition process such as CVD, ALD, or the like. Initially, the gap-fill layer 116 may cover the bottom integrated circuit die 100. A thinning process may be performed to level surfaces of the gap-fill layer 116, the semiconductor substrate 102, and the conductive vias 105. The thinning process may be a CMP process, a grinding process, an etch-back process, combinations thereof, or the like. Afterwards, the bonding layer 118 may be formed on the gap-fill layer 116 and the bottom integrated circuit die 100, and die connectors may be formed through the bonding layer 118 to connect to the conductive vias 105. The bonding layer 118 may be formed of an oxide such as silicon oxide, PSG, BSG, BPSG, a TEOS based oxide, or the like, which may be formed by a suitable deposition process such as CVD, ALD, or the like. The die connectors 120 may be formed by a damascene process, such as a single damascene process, a dual damascene process, or the like. The die connectors 120 may be formed of a metal, such as copper, aluminum, or the like, which can be formed by plating or the like. A planarization process such as a CMP, a grinding process, an etch-back process, combinations thereof, or the like, may be performed on the bonding layer 118 and the die connectors 120. In some embodiments, after the planarization process, surfaces of the bonding layer 118 and the die connectors 120 may be substantially coplanar or level (within process variations).

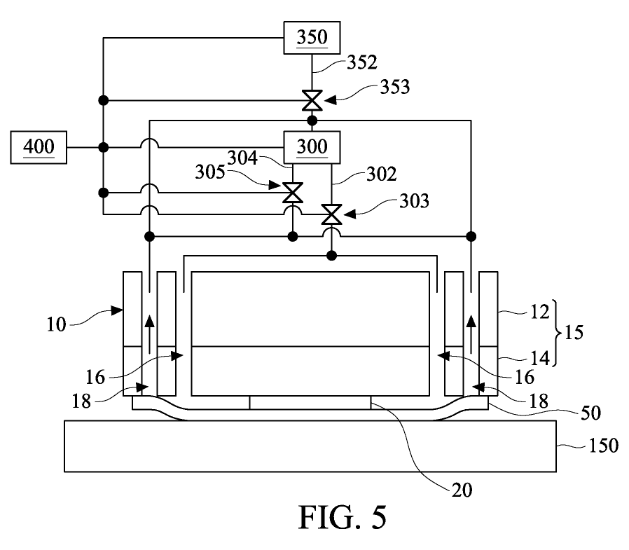

In FIG. 5, the controller 400 disables the vacuum in the vacuum channels 16 simultaneously while maintaining the vacuum in the switchable channels 18 to partially release the top integrated circuit die 50 by closing the vacuum valve 303 and keeping the vacuum valve 305 open. The respective process is illustrated as step 508 in the process flow 500 shown in FIG. 7B. As a result, the contact area between the central portion of the top integrated circuit die 50 and the wafer structure 150 may be gradually enlarged as the top integrated circuit die 50 is gradually flattened and the air at the interface between the top integrated circuit die 50 and the wafer structure 150 is gradually expelled, which may reduce or prevent voids between the top integrated circuit die 50 and the wafer structure 150 during the bonding process, thereby improving the yield and the reliability of the integrated circuit package. The peripheral portions of the top integrated circuit die 50 disposed underneath the bottom openings of the switchable channels 18 may be stilled spaced apart from the top surface of the wafer structure 150.

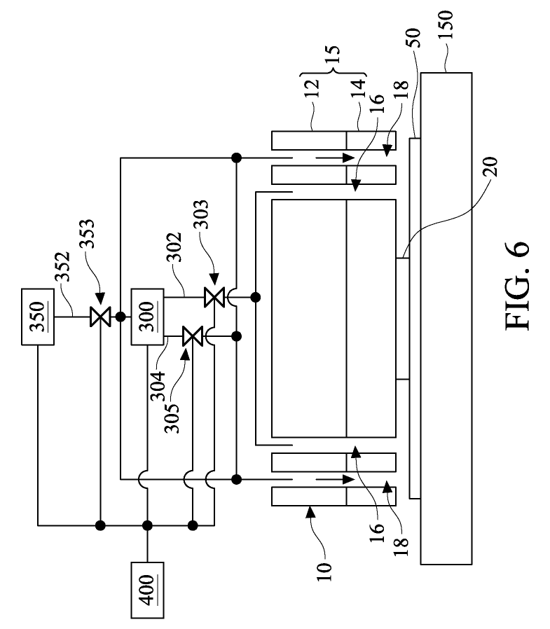

In FIG. 6, the controller 400 first disables the vacuum in the switchable channels 18 simultaneously to fully release the top integrated circuit die 50 by closing the vacuum valve 305, then creates blowing (e.g., positive pressure) in the switchable channels 18 simultaneously to flatten the peripheral portions of the top integrated circuit die 50 by activating the blower 350 and opening the gas valve 353. The respective process is illustrated as step 510 in the process flow 500 shown in FIG. 7B. When the controller 400 switches the switchable channels 18 from a vacuum mode to a blowing mode and creates the blowing in the switchable channels 18, the bottom openings of the switchable channels 18 may exert a blowing force on the top integrated circuit die 50. The peripheral portions of the top integrated circuit die 50 disposed underneath the bottom openings of the switchable channels 18 may be blown away from the bottom surface of the adapter 14 and propelled into contact with the top surface of the wafer structure 150 as the air at the interface between the top integrated circuit die 50 and the wafer structure 150 is gradually expelled. As a result, the warped top integrated circuit die 50 may be fully flattened and the contact area between the top integrated circuit die 50 and the wafer structure 150 may be the same as the area of the bottom surface of the top integrated circuit die 50, which may reduce or prevent voids between the top integrated circuit die 50 and the wafer structure 150 during the bonding process, thereby improving the yield and the reliability of the integrated circuit package.

Then the controller 400 first disables the blowing in the switchable channels 18 simultaneously by closing the gas valve 353. The duration of the blowing may be greater than 0.1 second, which may ensure sufficient blowing force is exerted on the peripheral portions of the top integrated circuit die 50 so that the top integrated circuit die 50 is sufficiently flattened. Afterwards, as shown in FIG. 7A, the bonding head 10 is directed by the controller 400 to move away from the top integrated circuit die 50. The respective process is illustrated as step 512 in the process flow 500 shown in FIG. 7B.

The pick-and-place process described above with respect to FIGS. 2A, 2B, 3, 4A, 4B, 5, 6, 7A, and 7B may be repeated if more than one top integrated circuit die 50 need to be placed on the wafer structure 150. As shown in FIGS. 3, 4A, and 5, the warpage of the top integrated circuit die 50 may be related to the dimensions of the top integrated circuit die 50 and the dimensions of the protrusion 20. The adapter 14, along with the protrusion 20, may be disconnected from the base 12 and a different adapter with a protrusion of different dimensions may be connected to the base 12, when another integrated circuit die of different dimensions needs to be placed on the wafer structure 150 by the bonding head 10.

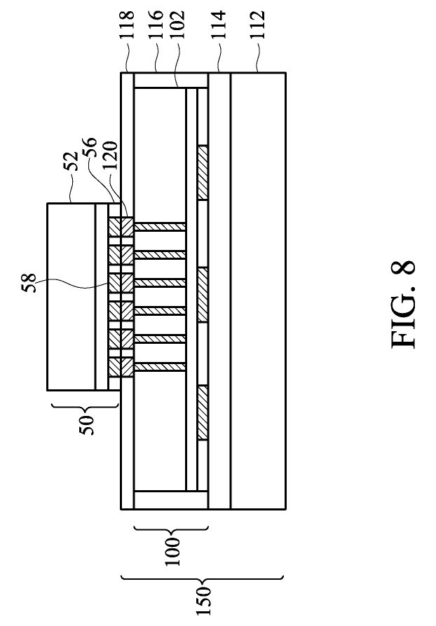

FIGS. 8, 9, 10, and 11 illustrate cross-sectional views of intermediate stages of the manufacturing of an integrated circuit package using the top integrated circuit die 50 and the wafer structure 150, in accordance with some embodiments. FIG. 8 illustrates aspects of the top integrated circuit die 50 and the wafer structure 150, after the pick-and-place process. The top integrated circuit die 50 may be placed on the wafer structure 150 in a way where each die connector 58 of the top integrated circuit die 50 is in contact with or disposed directly above the respective die connector 120 and the bonding layer 56 of the top integrated circuit die 50 is in contact with the bonding layer 118. The bonding layer 56 may be directly bonded to the bonding layer 118 through dielectric-to-dielectric bonding.

The bonding process may continue with a pressing step and an annealing step. In some embodiments, the pressing step is performed inside the bonding apparatus 450 and the annealing step is performed outside the bonding apparatus 450. During the pressing step, a small pressing force may be applied to press the top integrated circuit die 50 against the bonding layer 118 and the die connectors 120. The pressing step may be performed at a low temperature, such as room temperature. After the pressing step, the bonding between the bonding layer 56 of the top integrated circuit die 50 and the bonding layer 118 may be strengthened. The bonding between the bonding layer 56 and the bonding layer 118 may be further strengthened in the subsequent annealing step at a higher temperature. After the annealing step, the die connectors 58 of the top integrated circuit die 50 may be bonded to the respective die connectors 120. The die connectors 58 may be in physical contact with the die connectors 120 after the pressing step, or may expand to be brought into physical contact with the die connectors 120 during the annealing step. During the annealing step, the material of the die connectors 58 may intermingle or bond with the material of the die connectors 120, so that metal-to-metal bonds may be formed. After the annealing step the top integrated circuit die 50 may be electrically connected the bottom integrated circuit die 100 by the die connectors 120. Due to the flattening of the top integrated circuit die 50 on the wafer structure 150 during the pick-and-place process as described above, after the annealing step, interfaces between the peripheral portions, including respective edges, of the top integrated circuit die 50 and the wafer structure 150 may be free of voids.

FIG. 8 illustrates a front-to-back bonding configuration as an example, wherein the back side of the semiconductor substrate 102 of the bottom integrated circuit die 100 faces the front side of the semiconductor substrate 52 of the top integrated circuit die 50 after bonding. Other bonding configurations are contemplated, such as a front-to-front bonding configuration. In the front-to-front bonding configuration the front side of the semiconductor substrate 102 may face the front side of the semiconductor substrate 52. FIG. 8 illustrates a layout where one top integrated circuit die 50 overlays one bottom integrated circuit die 100 as an example, other layouts with other numbers of the top integrated circuit die 50 and the bottom integrated circuit die 100 are contemplated.

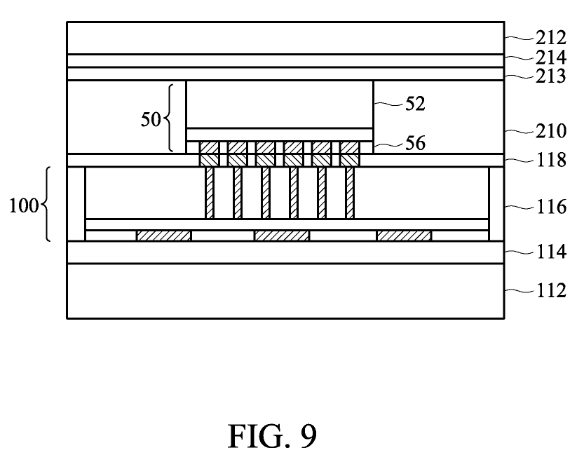

In FIG. 9, a gap-fill layer 210 is formed around the top integrated circuit die 50 and a carrier 212 is bonded to the top integrated circuit die 50 and the gap-fill layer 210. The gap-fill layer 210 may be formed by a same or similar method and formed of a same or similar dielectric material as the gap-fill layer 116. A thinning process may be performed to remove portions of the semiconductor substrate 52 and the gap-fill layer 210. The thinning process may be a CMP, a grinding process, an etch-back process, combinations thereof, or the like, which may be performed at the back side of the semiconductor substrate 52. After the thinning process, surfaces of the gap-fill layer 210 and the semiconductor substrate 52 may be substantially coplanar or level (within process variations). The carrier 212 may be a semiconductor carrier, a glass carrier, a ceramic carrier, or the like. The carrier 212 may be a wafer having a same or similar size as the carrier 112. In some embodiments, the carrier 212 is bonded to the top integrated circuit die 50 and the gap-fill layer 210 using bonding layers 213 and 214. The bonding layer 213 may be formed on the top integrated circuit die 50 and the gap-fill layer 210 and the bonding layer 214 may be formed on the carrier 212. The bonding layer 213 and the bonding layer 214 may each comprise a dielectric material, such as silicon dioxide or the like, and may be formed by a suitable deposition process such as CVD, ALD, or the like. The structure over the carrier 112 may be bonded to the carrier 212 by bonding the bonding layer 213 and the bonding layer 214 by a similar process used for bonding the bonding layer 118 and the bonding layer 56 described with respect to FIG. 8.

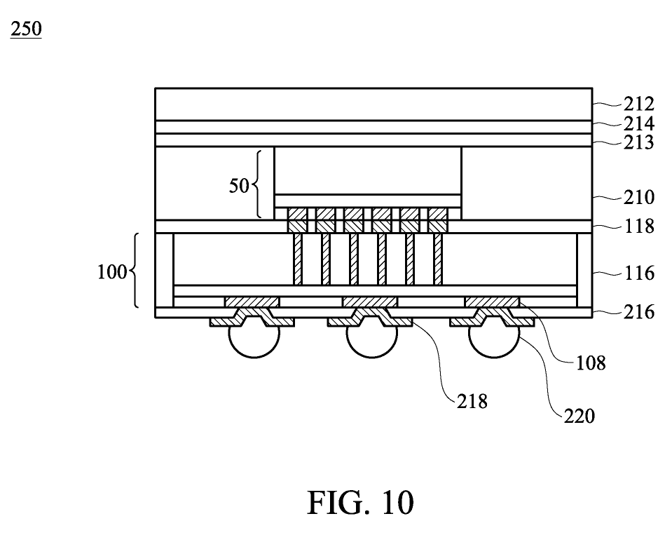

In FIG. 10, the carrier 112 and the adhesive 114 is removed, a dielectric layer 216 is formed on the gap-fill layer 116 and the bottom integrated circuit die 100, under-bump metallizations (UBMs) 218 are formed through the dielectric layer 216, and electrical connectors 220 are formed on the UBMs 218. The removal process of the carrier 112 and the adhesive 114 may include projecting a light beam such as a laser beam or a UV light beam on the adhesive 114 (shown in FIG. 9) so that the adhesive 114 decomposes upon exposure to the light beam and the carrier 112 may be removed. In some embodiments, the dielectric layer 216 comprises PBO, polyimide, a BCB-based polymer, or the like, and is formed by a suitable coating process such as spin coating, lamination, or the like. In some embodiments, the dielectric layer 216 comprises silicon dioxide, silicon nitride, or the like, and is formed by a suitable deposition process such as CVD, ALD, or the like. In some embodiments, a redistribution structure (not separately illustrated) may be formed on the gap-fill layer 116 and the bottom integrated circuit die 100 prior to forming the dielectric layer 216 to provide additional routing.

The UBMs 218 may have portions extending along a surface of the dielectric layer 216 and portions extending through the dielectric layer 216 to physically and electrically connect to the die connectors 108. As an example to form the UBMs 218, the dielectric layer 216 may be patterned to form openings exposing the underlying die connectors 108. A seed layer (not separately illustrated) may be formed on the dielectric layer 216, in the openings through the dielectric layer 216, and on the exposed portions of the die connectors 108. The seed layer may be a metal layer and may be formed using a suitable deposition process, such as physical vapor deposition (PVD) or the like. A photoresist may be then formed and patterned on the seed layer. A conductive material may be formed in the openings of the photoresist and on the exposed portions of the seed layer. The conductive material may be formed by plating, such as electroless plating, electroplating, or the like. Then the photoresist and portions of the seed layer on which the conductive material is not formed may be removed. The remaining portions of the seed layer and conductive material may form the UBMs 218.

Electrical connectors 220 may be formed on the UBMs 218. The electrical connectors 220 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. In some embodiments, the electrical connectors 220 comprise a conductive material such as solder, copper, aluminum, gold, nickel, silver, palladium, tin, the like, or a combination thereof, and are formed by initially forming a layer of solder through evaporation, electroplating, printing, solder transfer, ball placement, or the like, then reflowing the conductive material into the desired bump shapes. In some embodiments, the electrical connectors 220 comprise metal pillars, such as a copper pillar, formed by a sputtering, printing, electroplating, electroless plating, CVD, or the like, which are solder free and have substantially vertical sidewalls.

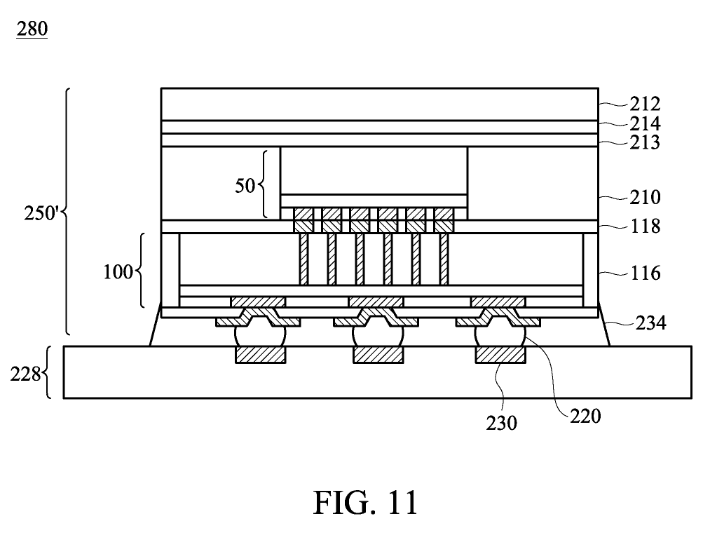

The processes discussed with respect to FIGS. 8 through 10 may be performed using wafer-level processing. The carrier 212 may be a wafer and may include many structures (not separately illustrated) similar to the one illustrated in FIG. 10. As such, the structure shown in FIG. 10 may be referred to as a wafer structure 250 and may be singulated in a subsequent singulation process to form individual integrated circuit package components 250’ (shown in FIG. 11). The wafer structure 250 may be placed on a tape supported by a frame and then singulated along scribe lines, so that the wafer structure 250 may be separated into discrete integrated circuit package components 250’. The singulation process may be a sawing process, a laser cutting process, or the like. A cleaning process or rinsing process may be performed after the singulation process.

In FIG. 11, the integrated circuit package component 250’ is bonded to a package substrate 228 and an underfill 234 is formed between the integrated circuit package component 250’ and the package substrate 228. The package substrate 228 may include bonding pads 230. In some embodiments, the package substrate 228 comprises materials such as fiberglass reinforced resin, bismaleimide-triazine (BT) resin, or the like. In some embodiments, the package substrate 228 comprises materials such as silicon, germanium, silicon germanium, silicon carbide, gallium arsenic, indium arsenide, indium phosphide, silicon germanium carbide, gallium arsenic phosphide, gallium indium phosphide, or the like.

The package substrate 228 may include active and passive devices (not separately illustrated), such as transistors, capacitors, resistors, combinations thereof, or the like. The package substrate 228 may comprise metallization layers and vias (not separately illustrated) physically and electrically connected to the bonding pads 230. The metallization layers may be formed over the active and passive devices and may electrically connect the active and passive devices to form functional circuitry. The metallization layers may be alternating layers of dielectric material and conductive material with vias interconnecting the layers of conductive material. In some embodiments, the package substrate 228 is free of active and passive devices.

During the bonding process the electrical connectors 220 may be reflowed to bond the integrated circuit package component 250’ to the bonding pads 230 of the package substrate 228. The electrical connectors 220 may electrically and physically connect the package substrate 228 to the integrated circuit package component 250’. In some embodiments, a solder resist (not separately illustrated) is disposed on the package substrate 228. The electrical connectors 220 may be disposed in openings in the solder resist to electrically and physically connect to the bond pads 230. The solder resist may be used to protect areas of the package substrate 228 from external damage. The underfill 234 may surround the electrical connectors 220 and protect the joints resulting from the reflowing of the electrical connectors 220. The underfill 234 may be formed by a capillary flow process after the integrated circuit package component 250’ is attached or by a suitable deposition method before the integrated circuit package component 250’ is attached. The underfill 234 may be subsequently cured. The structure shown in FIG. 11 may be referred to as an integrated circuit package 280.

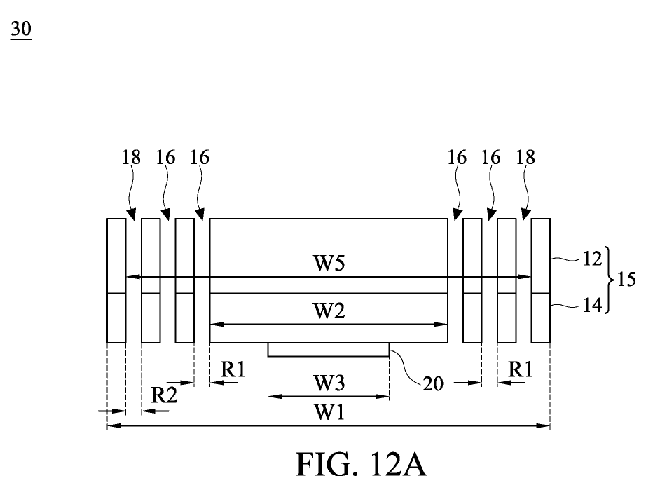

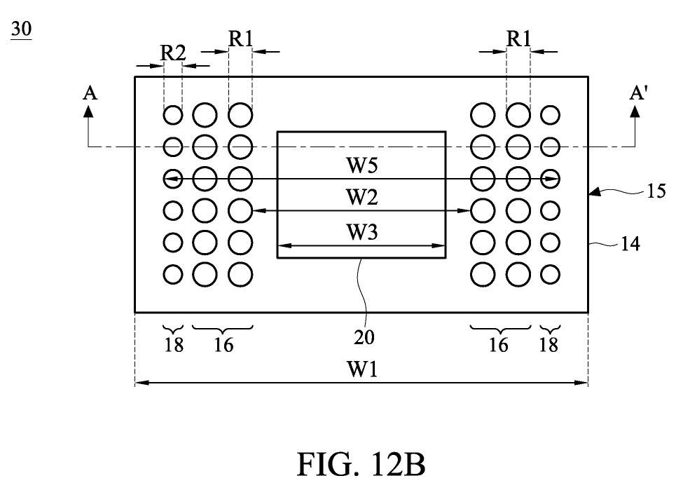

FIGS. 12A and 12B show a cross-sectional view and a bottom-up view of a bonding head 30, respectively. The bonding head 30 is similar to the bonding head 10 shown in FIG. 1A and 1B, wherein two columns of the vacuum channels 16 are disposed between a column of the switchable channels 18 and the protrusion 20 on each side of the main body 15 in the bottom-up view of the bonding head 30. The cross-sectional view of the bonding head 30 shown in FIGS. 12A may be obtained from the reference cross-section A-A’ in the bottom-up view of the bonding head 30 shown in FIG. 12B, wherein like reference numerals refer to like features. The layout of the vacuum channels 16 and the switchable channels 18 of the bonding head 10 in FIGS. 1A and 1B as well as the bonding head 30 in FIGS. 12A and 12B are provided as examples. In some embodiments, more than two columns of the vacuum channels 16 may be disposed between the column of the switchable channels 18 and the protrusion 20 on each side of the main body 15. In some embodiments, more than one column of the switchable channels 18 may be disposed on each side of the main body 15. Other numbers, shapes, sizes, and arrangements of the vacuum channels 16 and the switchable channels 18 are also contemplated.

Various embodiments are described above in the context of forming a system on integrated chips (SoIC) package configuration. It should be understood that various embodiments may also be adapted to apply to forming other package configurations, such as integrated fan-out on substrate (InFO), chip on wafer on substrate (CoWoS) or the like.

The embodiments may have some advantageous features. By utilizing the bonding apparatus 450 to place the top integrated circuit die 50 on the wafer structure 150, the top integrated circuit die 50 may be first warped, then gradually flattened on the wafer structure 150, and the air between the top integrated circuit die 50 and the wafer structure 150 may be gradually expelled, which may reduce or prevent voids between the top integrated circuit die 50 and the wafer structure 150 during the bonding process, thereby improving the yield and the reliability of the integrated circuit package 280.

In an embodiment, a bonding apparatus includes a vacuum pump; a blower; a controller communicatively coupled to the vacuum pump and the blower; and a bonding head, wherein the bonding head includes a main body; a first vacuum channel in the main body, wherein the first vacuum channel is connected to the vacuum pump; and a first switchable channel in the main body, wherein the first switchable channel is connected to the vacuum pump and the blower. In an embodiment, the first vacuum channel has a circular opening with a first diameter in a bottom-up view and the first switchable channel has a circular opening with a second diameter in the bottom-up view, and wherein the first diameter is larger than or equal to the second diameter. In an embodiment, the second diameter is greater than 0.1 mm. In an embodiment, the first switchable channel is between a first edge of the main body and the first vacuum channel in a bottom-up view. In an embodiment, the bonding apparatus further includes a second switchable channel in the main body and a protrusion on a bottom surface of the main body, wherein the protrusion is disposed in a central region of the bottom surface of the main body, wherein the protrusion is between the second switchable channel and the first vacuum channel in a bottom-up view, and wherein the second switchable channel is connected to the vacuum pump and the blower. In an embodiment, the bonding apparatus further includes a second vacuum channel in the main body, wherein the second vacuum channel is between the second switchable channel and the protrusion in the bottom-up view, and wherein the second vacuum channel is connected to the vacuum pump. In an embodiment, the main body has a first width, wherein the first vacuum channel is spaced apart from the second vacuum channel by a second width, and wherein the second width is greater than or equal to half of the first width.

In an embodiment, a bonding apparatus includes a controller; a vacuum pump, a first vacuum valve, and a second vacuum valve communicatively coupled to the controller; a blower and a gas valve communicatively coupled to the controller; and a bonding head, wherein the bonding head includes a main body; a protrusion on a central portion of a bottom surface of the main body; a first plurality of vacuum channels in the main body, wherein the first plurality of vacuum channels are connected to the vacuum pump through the first vacuum valve, and wherein the controller is configured to create vacuum in the first plurality of vacuum channels simultaneously; and a first plurality of switchable channels in the main body, wherein the first plurality of switchable channels are connected to the vacuum pump through the second vacuum valve and to the blower through the gas valve, wherein the controller is configured to create vacuum in the first plurality of switchable channels simultaneously or create blowing in the first plurality of switchable channels simultaneously. In an embodiment, the bonding apparatus further includes a second plurality of switchable channels in the main body, wherein the controller is configured to create vacuum in the first plurality of switchable channels and the second plurality of switchable channels simultaneously or create blowing in the first plurality of switchable channels and the second plurality of switchable channels simultaneously, wherein openings of the first plurality of switchable channels form a first column of openings along a first edge of the main body in a bottom-up view, and wherein openings of the second plurality of switchable channels form a second column of openings along a second edge of the main body opposite to the first edge in the bottom-up view. In an embodiment, the bonding apparatus further includes a second plurality of vacuum channels in the main body, wherein the controller is configured to create vacuum in the first plurality of vacuum channels and the second plurality of vacuum channels simultaneously, wherein openings of the first plurality of vacuum channels form one or more columns of openings between the first column of openings and the protrusion in the bottom-up view, and wherein the second plurality of vacuum channels form one or more columns of openings between the second column of openings and the protrusion in the bottom-up view. In an embodiment, each of the first plurality of vacuum channels has a same first diameter, wherein each of the first plurality of switchable channels has a same second diameter, and wherein the first diameter is greater than the second diameter.

In an embodiment, a method for forming an integrated circuit package includes attaching a first substrate to a bonding head by creating negative pressure in a first vacuum channel and a first switchable channel in the bonding head, wherein the first switchable channel is between a first sidewall of the bonding head and the first vacuum channel; placing the first substrate to a top surface of a second substrate and forming bonding between the first substrate and the second substrate; releasing the negative pressure in the first vacuum channel while maintaining the negative pressure in the first switchable channel; and after releasing the negative pressure in the first vacuum channel, releasing the negative pressure in the first switchable channel and blowing the first substrate away from the bonding head by creating positive pressure in the first switchable channel. In an embodiment, after attaching the first substrate to the bonding head, a central portion of the first substrate is in direct contact with a bottom surface of a protrusion of the bonding head and a peripheral portion of the first substrate is in direct contact with a bottom surface of a main body of the bonding head, and wherein the protrusion of the bonding head is on the bottom surface of the main body of the bonding head. In an embodiment, after placing the first substrate to the top surface of the second substrate, a central portion of the first substrate is in direct contact with the top surface of the second substrate and a peripheral portion of the first substrate is spaced apart from the top surface of the second substrate. In an embodiment, after blowing the first substrate away from the bonding head, the peripheral portion of the first substrate is in direct contact with the top surface of the second substrate. In an embodiment, blowing the first substrate away from the bonding head lasts for more than 0.1 second. In an embodiment, the first substrate is warped by the bonding head and then flattened by the bonding head. In an embodiment, the method further includes annealing the first substrate and the second substrate after releasing the negative pressure in the first switchable channel and blowing the first substrate away from the bonding head, wherein after annealing the first substrate and the second substrate, an interface between an edge of the first substrate and the second substrate is free of voids. In an embodiment, the method further includes annealing the first substrate and the second substrate after releasing the negative pressure in the first switchable channel and blowing the first substrate away from the bonding head, wherein annealing the first substrate and the second substrate strengthens the bonding between the first substrate and the second substrate. In an embodiment, the main body has a first width between the first sidewall of the main body and a second sidewall of the main body opposite to the first sidewall, wherein the first substrate has a second width, and wherein the first width is larger than the second width.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming an integrated circuit package, the method comprising:
attaching a first substrate to a bonding head by creating negative pressure in a first vacuum channel and a first switchable channel in the bonding head, wherein the first switchable channel is between a first sidewall of the bonding head and the first vacuum channel;
placing the first substrate to a top surface of a second substrate and forming bonding between the first substrate and the second substrate;
releasing the negative pressure in the first vacuum channel while maintaining the negative pressure in the first switchable channel; and
after releasing the negative pressure in the first vacuum channel, releasing the negative pressure in the first switchable channel and blowing the first substrate away from the bonding head by creating positive pressure in the first switchable channel.

2. The method of claim 1, wherein after attaching the first substrate to the bonding head, a central portion of the first substrate is in direct contact with a bottom surface of a protrusion of the bonding head and a peripheral portion of the first substrate is in direct contact with a bottom surface of a main body of the bonding head, and wherein the protrusion of the bonding head is on the bottom surface of the main body of the bonding head.

3. The method of claim 1, wherein after placing the first substrate to the top surface of the second substrate, a central portion of the first substrate is in direct contact with the top surface of the second substrate and a peripheral portion of the first substrate is spaced apart from the top surface of the second substrate.

4. The method of claim 3, wherein after blowing the first substrate away from the bonding head, the peripheral portion of the first substrate is in direct contact with the top surface of the second substrate.

5. The method of claim 1, wherein blowing the first substrate away from the bonding head lasts for more than 0.1 second.

6. The method of claim 1, wherein the first substrate is warped by the bonding head and then flattened by the bonding head.

7. The method of claim 1, further comprising annealing the first substrate and the second substrate after releasing the negative pressure in the first switchable channel and blowing the first substrate away from the bonding head, wherein after annealing the first substrate and the second substrate, an interface between an edge of the first substrate and the second substrate is free of voids.

8. The method of claim 1, further comprising annealing the first substrate and the second substrate after releasing the negative pressure in the first switchable channel and blowing the first substrate away from the bonding head, wherein annealing the first substrate and the second substrate strengthens the bonding between the first substrate and the second substrate.

9. The method of claim 1, wherein the main body has a first width between the first sidewall of the main body and a second sidewall of the main body opposite to the first sidewall, wherein the first substrate has a second width, and wherein the first width is larger than the second width.

10. A method for forming an integrated circuit package, the method comprising:
providing a first wafer structure, wherein the first wafer structure comprises a first substrate, a first bonding layer on a first side of the first substrate, and a first bonding pad in the first bonding layer;
attaching a second side of the first substrate to a bonding head by creating negative pressure in a first vacuum channel and in a first switchable channel of the bonding head;
placing the first wafer structure on a second wafer structure by moving the bonding head, wherein the second wafer structure comprises a second substrate, a second bonding layer on the second substrate, and a second bonding pad in the second bonding layer, and wherein the first bonding layer is in contact with the second bonding layer and the first bonding pad is in contact with the second bonding pad;
releasing the negative pressure in the first vacuum channel while maintaining the negative pressure in the first switchable channel; and
releasing the negative pressure in the first switchable channel.

11. The method of claim 10, wherein the first vacuum channel has a circular opening with a first diameter in a bottom-up view and the first switchable channel has a circular opening with a second diameter in the bottom-up view, and wherein the first diameter is larger than the second diameter.

12. The method of claim 10, wherein the bonding head comprises a main body and a protrusion on a bottom surface of the main body, wherein the first vacuum channel and the first switchable channel are in the main body, and wherein the first vacuum channel is between the first switchable channel and the protrusion a bottom-up view.

13. The method of claim 12, wherein a central portion of the first substrate is in contact with the protrusion and a peripheral portion of the first substrate is in contact with the main body after attaching the second side of the first substrate to the bonding head.

14. The method of claim 10, further comprising blowing the first substrate away from the bonding head by creating positive pressure in the first switchable channel after releasing the negative pressure in the first switchable channel.

15. The method of claim 14, wherein the first wafer structure is warped before releasing the negative pressure in the first vacuum channel, and wherein the first wafer structure is flattened after blowing the first wafer structure away from the bonding head.

16. A method for forming an integrated circuit package, the method comprising:
providing a first wafer structure, wherein the first wafer structure comprises a first substrate and a first bonding layer on a first side of the first substrate;
attaching a second side of the first substrate to a bonding head by creating vacuum in a first vacuum channel and in a first switchable channel in a main body of the bonding head, wherein the bonding head comprises a protrusion on a bottom surface of the main body, and wherein a central portion of the first substrate is in contact with the protrusion and a peripheral portion of the first substrate is in contact with the main body;
placing the first wafer structure on a second wafer structure by moving the bonding head, wherein the second wafer structure comprises a second substrate and a second bonding layer on the second substrate, and wherein the first bonding layer is in contact with the second bonding layer;
releasing the vacuum in the first vacuum channel while maintaining the vacuum in the first switchable channel;
releasing the vacuum in the first switchable channel; and
blowing the first substrate away from the bonding head by creating airflow in the first switchable channel.

17. The method of claim 16, wherein the first bonding layer and the second bonding layer has a first contact area after the placing the first wafer structure on the second wafer structure, wherein the first bonding layer and the second bonding layer has a second contact area after releasing the vacuum in the first vacuum channel, and wherein the second contact area is greater than the first contact area.

18. The method of claim 17, wherein the first bonding layer and the second bonding layer has a third contact area after blowing the first substrate away from the bonding head, and wherein the third contact area is greater than the second contact area.

19. The method of claim 16, wherein the first switchable channel is adjacent to a first edge of the main body, and wherein the first switchable channel is between the first edge of the main body and the first vacuum channel.

20. The method of claim 16, further comprising:
pressing the first wafer structure against the second wafer structure; and
annealing the first wafer structure and the second wafer structure.
